(19) United States
(12) Patent Application Publication
(10) Pub. No.: US 2014/0174534 A1
(43) Pub. Date: Jun. 26, 2014

(54) APPARATUS, SYSTEMS AND METHODS FOR COLLECTING AND CONVERTING SOLAR ENERGY

(71) Applicant: Solartrack, LLC, New York, NY (US)

(72) Inventor: William D. Bickmore, Saint George, UT (US)

(73) Assignee: Solartrack, LLC, New York, NY (US)

(21) Appl. No.: 14/137,603

(22) Filed: Dec. 20, 2013

Related U.S. Application Data
(60) Provisional application No. 61/745,465, filed on Dec. 21, 2012.

(51) Int. Cl. H01L 31/0216; H01L 31/18

(52) U.S. Cl. CPC H01L 31/02168; H01L 31/18
USPC 136/259; 438/69

(57) ABSTRACT

Nanoparticles are used to enhance the light gathering and converting abilities of a photo voltaic (PV) cell. The nanoparticles may be incorporated into a substrate and disposed a desired distance from the PV cell to create a plasmon. The nanoparticles may effect a wavelength shift (e.g., a “red shift”) to better align the wavelength of available light with the sensitivity of the PV cell. The nanoparticles may also be used to trap the light above the PV cell to effect better absorption of the light. The nanoparticles may include composite nanoparticles having, for example, a metallic core and a substantially transparent shell or coating about the core. The nanoparticles may be constructed to provide uniform distribution in a carrier medium.

### CROSS-REFERENCE TO RELATED APPLICATIONS

This application claims priority to U.S. Provisional Patent Application No. 61/745,465, filed Dec. 21, 2012, entitled APPLICATION OF NANOPARTICLES (NPs) TO ENHANCE THE ABILITY OF PHOTOVOLTAIC (PV) CELLS TO EXTRACT MORE ENERGY FROM THE SUN WHEN GENERATING ELECTRICAL POWER, the disclosure of which is incorporated by reference herein, in its entirety.

### TECHNICAL FIELD

The present invention relates generally to the collection of solar energy and, more specifically to the use of nanoparticles in collecting and converting solar energy in various apparatuses, systems and methods.

### BACKGROUND

Commercially available photovoltaic (PV) cells are currently believed to be about 5%-20% efficient in their conversion of sun light photon energy into electrical energy under optimal conditions. The optimal output of electrical energy of PV cells is dependent on a variety of factors. For example, the angle of incidence (AOI) of the sun light as it strikes the PV cell has an impact on the electrical output. The electrical load on the PV cell also has an influence on the efficiency of the PV cell. The loss of photon energy due to reflection from the surface of the solar module's protective glass surface has an impact on the resulting electrical output. Certainly the level of energy present in the photons entering the PV is important, as is the ability of the PV cell to convert the energy of the solar spectrum at various wavelengths of light into electrical energy. Many factors relating to the physics of PV cell substrate also have an impact on the efficiency of the system including doping processes and the construction of the solid state diodes formed the PV cell.

One particular issue with regard to the efficiency of PV cells includes matching the sensitivity or response of a given material (e.g., crystalline silicon) being used by a PV cell to the output energy from the sun. For example, referring to the graph shown in FIG. 1, a first curve 10 depicts the power generated by the sun at various wavelengths. The peak power generated by the sun, or peak photon output, occurs approximately between the wavelengths of 425 nm wavelength and 525 nm. It is noted that the peak power output of the sun is depicted as “1” on the vertical axis representing 100% of the suns normal peak power output.

A second curve 20 shows the sensitivity of a conventional crystalline silicon PV solar cell at various wave lengths with the peak sensitivity of the PV solar cell occurring at about 850 nm. The highest level of the sensitivity of the PV cell is depicted as “1” on the vertical axis. A third curve 30 is superimposed over the first two graphs 10 and 20 to show the “compatibility” or overlap of the suns photon output compared to the sensitivity of a conventional PV cell. Because the peak sensitivity of a silicon solar cell and the peak output of the sun are incongruous (the peaks being separated by several hundred nanometers). Because of the mismatch between the peak output of the sun and the sensitivity of the PV cell, the PV cell is only able to utilize a portion of the sun's available energy when sunlight is impinging upon the PV cell. The theoretical peak usage curve of the solar energy (i.e., graph 30) is found by multiplying the percentage of sensitivity of the PV cell with the power generated by the sun at a given wavelength. In this case, the third graph 30 exhibits a peak at approximately 675 nm—somewhere between the peak of the sun's output and the PV cell's peak sensitivity.

With present payback periods of 20 years or more for installation of PV based solar energy systems, the adoption of such technology has been slow, at best. State and Federal Governments, as well as utility companies, have offered financial incentives to foster adoption of such systems, but adoption is still relatively slow. Improving the efficiency of solar energy systems will reduce the payback period and help to make solar energy more acceptable to consumers.

As such, it is a continual desire of the solar energy industry to improve the performance of solar energy systems. It would be advantageous to provide apparatuses, systems and methods of collecting solar energy that are efficient, that are relatively inexpensive and that are readily adaptable by the solar market, including residential users.

### BRIEF SUMMARY OF THE INVENTION

In accordance with the present invention, various embodiments of the invention, apparatuses, systems and methods are provide for collecting and converting solar energy. In one embodiment a solar energy apparatus is provided. The apparatus includes a photovoltaic (PV) cell and a material layer associated with the PV cell. The material layer has a plurality of nanoparticles (NPs) which are each spaced from adjacent NPs at intervals of approximately 10% to 150% of an average NP diameter. The material layer is positioned relative to the PV cell to provide an optically transparent material gap between the NPs and the PV cell.

In accordance with one embodiment, the NPs comprise at least one of silver, gold, and copper. In one embodiment, the NPs include a metallic core and a substantially transparent shell. For example, the shell may be comprised of silica. In one particular embodiment, the shell may exhibit a thickness of approximately 10 to 20 nanometers.

In one embodiment, the NPs exhibit an absolute zeta charge of approximately 30 mV or greater. The NPs may additionally exhibit an average diameter of approximately 2 nanometers to approximately 10 nanometers.

In another embodiment, the NPs are substantially spherical and exhibit an average diameter of approximately 10 to approximately 250 nanometers.

In another embodiment, the NPs include triangular platelets exhibiting a height from a base to an apex of approximately 150 nm and a thickness of approximately 10 to approximately 40 nm.

In one embodiment, the NPs exhibit an inter-sphere spacing of wherein the NPs exhibit an inter-sphere spacing of approximately fifty percent to approximately 300 percent of the diameter of the NPs.

In accordance with another embodiment, a method of manufacturing a solar energy apparatus is provided. The method comprises providing a photovoltaic (PV) cell and disposing a plurality of nanoparticles (NPs) adjacent to the PV cell to create a plasmon, wherein there is an optically transparent material gap between the plasmon and the PV cell.

In one embodiment disposing a plurality of NPs adjacent to the PV cell includes disposing a plurality of composite NPs. For example, the NPs may be provided with a metallic core and an optically transparent shell.

In accordance with another embodiment, a method is provided of retrofitting a solar energy device having a PV cell. The method comprises disposing a plurality of NPs adjacent to the PV cell to create a plasmon having an optically transparent material gap between the plasmon and the PV cell.

The method may further comprise disposing the plurality of NPs on an existing substrate of the solar energy device positioned above the PV cell.

In one embodiment, the method may include placing a film containing the plurality of NPs on the substrate. In another embodiment, the method may include replacing an existing substrate of the solar energy cell with a new substrate including the plurality of NPs.

In one embodiment, the method includes suspending the NPs in a solution with the NPs exhibiting a substantially uniform spacing, wherein the substantially uniform spacing is controlled, at least in part, by the thickness of the NPs shells.

In accordance with yet another embodiment of the present invention, a method is provided for manufacturing a substrate. The method includes providing an aqueous solution containing high zeta charge, substantially spherical nanoparticles (NPs), forming a gelatin of the solution, coating a transparent polymer web substrate with the gelatin and removing moisture from the coated polymer web. In one embodiment, the method may include providing the NPs as silver NPs.

In certain embodiments, the method includes providing NPs that exhibit an absolute zeta charge of approximately 30 mV or greater.

In one embodiment, the NPs may exhibit an average diameter of approximately 2 nanometers to approximately 10 nanometers.

In one embodiment, the NPs may be suspended within the solution at a substantially uniform distribution exhibiting an inter-nanoparticle spacing of approximately 1 nanometer to approximately 5 nanometers.

In one embodiment, forming the gelatin may include forming a gelatin that comprises polyurethane.

Features and elements of one embodiment may be combined with features and elements of other embodiments without limitation.

### BRIEF DESCRIPTION OF THE SEVERAL VIEWS OF THE DRAWINGS

The foregoing and other advantages of the invention will become apparent upon reading the following detailed description and upon reference to the drawings in which:

FIG. 1 is a graph showing peak power or photon output of the sun compared to the sensitivity of a conventional PV solar cell;

FIGS. 2-8 are cross-sectional views of various nanoparticles and composite nanoparticles according to embodiments of the invention;

FIGS. 9 and 10 are perspective views of various nanoparticles and composite nanoparticles according to embodiments of the invention

FIG. 11 is a graph comparing the power or photon output of the sun compared to a PV cell in accordance with an embodiment of the invention;

FIG. 12 shows a layer of nanoparticles in a random distribution and the interaction of light with the layer;

FIGS. 13A and 13B each show a layer of uniformly distributed nanoparticles in association with a PV cell according to different embodiments of the invention;

FIG. 14 is a partial cross-sectional view of a solar module;

FIG. 15 is a partial cross-sectional view of a solar module in accordance with an embodiment of the present invention;

FIG. 16 is a partial cross-sectional view of a solar module in accordance with another embodiment of the present invention;

FIG. 17 is a partial cross-sectional view of a solar module in accordance with another embodiment of the present invention;

FIG. 18 is a partial cross-sectional view of a solar module in accordance with another embodiment of the present invention;

FIGS. 19 and 20 are graphs depicting the results of Mei's solution for certain configurations of NPs.

It is noted that the drawings presented herein are not to scale. Additionally, common reference numbers used between multiple drawings represent similar, thought not necessarily identical, features or elements.

### DETAILED DESCRIPTION OF THE INVENTION

Embodiments of the present invention include methods, systems and apparatuses that may incorporate nanoparticles (NPs) as optical enhancements to silicon based and other types of photovoltaic (PV) cells used to capture and/or convert solar energy. As used herein, a NP is a small, discrete object having similar properties as if it were a larger unit of the same material. The small size of NPs is relative. While some authors restrict the definition of a NP to objects which are at most a few hundred nanometers in size, others may consider particles which are as large as 10,000 nanometers as NPs. NPs which are between 1 and 100 nanometers are generally classified as fine NPs. Molecules are not considered to be NPs.

As described in further detail below, when used in conjunction with PV cells, NPs can enhance the photocell's ability to more efficiently capture and convert more of the available photonic energy into electrical energy. Various embodiments described herein may utilize silver, gold, copper and/or other metal NPs. In some embodiments, the metallic NPs may be used in combination with other materials. For example, in some embodiments, the metallic materials of the NPs may be coated with a thin, transparent layer of material such as silica. In other embodiments, silica cores (or other material cores) may be coated with a thin metallic layer. In yet other embodiments, the NPs may be coated with or impregnated with certain dyes which assist in shifting the wavelengths of impinging light to wavelengths which are more efficiently utilized by crystalline silicon PV cells. Shifting the naturally occurring wavelengths of the solar spectrum to longer wavelengths (e.g., “red shifting”) may help to better match the wavelength spectral profile of incoming electromagnetic solar radiation to that which more closely matches the spectral sensitivity of silicon PV cells so as to enable more efficient generation of electrical power.

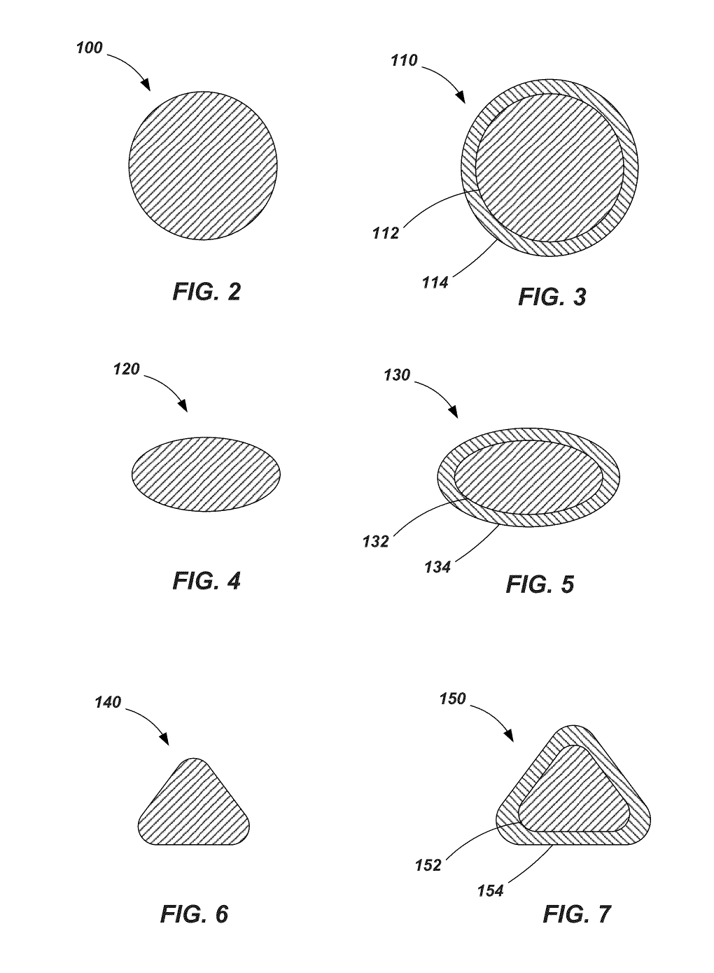

FIGS. 2-8, show various configurations of NPs which may be used in conjunction with PV cells to enhance the electrical generating capacity of the PV cells by making the energy of more photons useable by the PV cell. FIG. 2 shows a cross section of a substantially spherical metallic NP 100 (e.g., gold, silver, copper). The NP 100 may exhibit a diameter of, for example, approximately 10 nm to approximately 250 nm. It is noted that the terms “approximately” and “substantially” are used herein are to indicate that the values may be within industry accepted tolerances rather than being absolute. Referring to FIG. 3, a cross-sectional view of a substantially spherical composite NP 110 is shown. The NP 110 includes a substantially spherical metal core 112 with a coating 114 of a substantially transparent material such as silica. Again, the metal core 112 may exhibit a diameter of approximately 10 nm to approximately 250 nm in accordance with one embodiment, while the transparent coating may exhibit a thickness of approximately 5 nm to approximately 20 nm. The coating may serve a number of purposes. For example, the coating may serve to functionalize the NP to be compatible with the material in which it is suspended. It may also be used as a transparent optical path in tightly packed NPs. Additionally, it may be used as a material to absorb fluorescent dyes used to cause a wavelength shift. Further, it may serve as a dielectric. The NP 110 shown in FIG. 3, being formed of multiple materials, may be referred to as a composite NP. In another embodiment, the composite NP may be configured to have a non-metallic core (e.g., silica) and a thin coating of a metallic material disposed around the core. Composite NPs may be obtained commercially from providers such as nanoComposix of San Diego, Calif.

FIG. 4 shows a cross section of a substantially ellipsoidal metallic NP 120. In one example, the dimension along the major axis of the NP 120 may be between approximately 20 nm and approximately 250 nm while the dimension along the minor axis may be approximately 100 nm or less. Referring to FIG. 5, a substantially ellipsoidal composite NP 130 is shown. The NP 130 includes a metallic core 132 and a substantially transparent coating 134 of a material such as silica. The metal core 132 may exhibit a dimension along the major axis of between approximately 20 nm and approximately 250 nm and a dimension along the minor axis of approximately 100 nm or less. The coating may exhibit a thickness of approximately 5 nm to approximately 20 nm. In another embodiment, the construction may be reversed with core being formed of a non-metallic material (e.g., silica) and the shell or coating comprising a thin metallic layer of metallic material.

FIG. 6 shows a cross section of a metallic NP 140 formed as a substantially triangular platelet. In one example, the NP 140 may exhibit a height (measured along a line that is perpendicular to the base and extending from base to the apex) that is between approximately 100 nm and approximately 200 nm with a thickness (i.e., measured in a direction that is perpendicular to the plane of the drawing figure) of between approximately 10 nm and approximately 40 nm. FIG. 7 shows a cross section of a composite NP 150 formed as a substantially triangular platelet. The composite NP 150 includes a substantially metallic core 152 exhibiting a substantially triangular platelet geometry, and a substantial transparent material coating 154 of a material such as silica. In one embodiment, the core may be configured substantially similarly to the NP 140 shown in FIG. 6, and the coating may exhibit a thickness of approximately 5 nm to approximately 20 nm. In another embodiment, the construction may be reversed with the core being formed of a non-metallic material (e.g., silica) and the shell or coating comprising a thin metallic layer of metallic material.

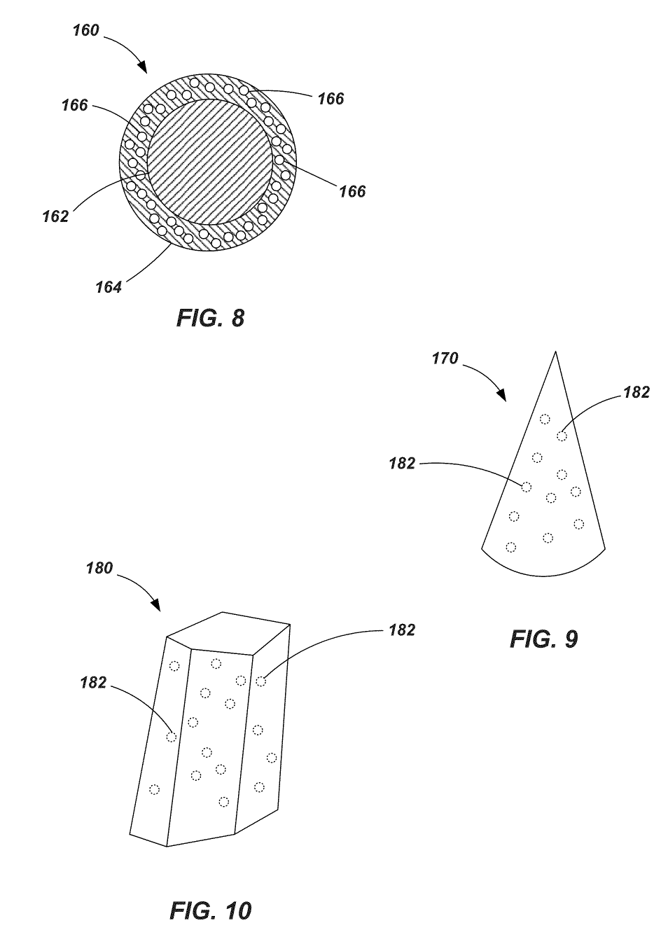

Referring to FIG. 8, a cross-sectional view is shown of a composite NP 160 with a metallic core 162 and a coating of a substantially transparent material 164 such as silica. The NP may exhibit a variety of geometries including substantially spherical or ellipsoidal geometries. A spectral shifting dye 166 (e.g., a fluorescent dye) is embedded in, coated on, or otherwise mixed with, the transparent material 164. The dye 166 may assist in shifting the wavelength to longer wavelengths (“red shifting”) or shorter wavelengths (“blue shifting”) to help align the wavelength of the available light to the sensitivity of an associated PV cell. For example, the dye may include any of the dyes listed in TABLE 1 below, although other dyes may also be used.

TABLE 1

| | EXCITATION λ | EMISSION λ |
|---|---|---|
| FLUORESCENT DYE | (nm) | (nm) |
| Abberior Star | 437 | 515 |
| Alexa Fluor 405 | 401 | 421 |
| Alexa Fluor 430 | 434 | 541 |
| Alexa Fluor 610X | 612 | 628 |
| Alexa Fluor 700 | 702 | 723 |
| Cyanine Cy3 | 550 | 570 |
| Cyanine Cy5 | 650 | 670 |
| DyLight 550 | 562 | 576 |
| DyLight 650 | 654 | 673 |
| DyLight 750 | 754 | 776 |
| Fluorescein | 494 | 521 |
| Rhodamine B | 540 | 625 |
| Rhodamine 6G | 526 | 555 |
| Rhodamine 123 | 511 | 534 |
| Texas Red | 596 | 615 |

Referring to FIGS. 9 and 10, perspective views are shown of NPs configured as a nano-cone 170 and a nano-rod 180. The nano-cones 170 and nano-rods 180 are formed of a substantially transparent material such as silica. A spectral shifting dye 182 may be coated on, embedded in, or otherwise mixed with, the transparent material. The shapes of the nano-cones 170 and nano-rods 180 may additional assist in shifting the angle of incidence of the light impinging upon a PV cell in order to bring the angle of incidence closer to perpendicular with the light collecting surface of a PV cell, making it more suitable for power generation by the PC cell.

The NPs depicted in FIGS. 2-10 are representative of various types of NPs that may be used in accordance with embodiments of the present invention. Additionally, a single type of NP need not be used exclusive of other types of NPs. Rather, multiple types of NPs may be used together in various combinations.

Prior to use in conjunction with a PV cell or some other component of a solar energy system, the NPs may undergo a process of functionalization to provide the NPs with certain desirable characteristics. For example, the NPs may be functionalized to enable a desired distribution pattern of the NPs within a selected carrier medium (e.g., when embedded within in a polymer, such as polyurethane). For example, functionalization may include tailoring the surface coating of NPs in order to regulate stability, solubility, and targeting. A coating that is multivalent or polymeric confers high stability. When certain distribution patterns of the NPs within a carrier medium are desired, it can be important to properly functionalize the NPs prior to being dispensed within the media. Improperly prepared NPs may agglomerate into large clusters, or may exhibit a streaking or other non-uniform distribution patterns, and otherwise inhibit optimal spacing between the NPs within the suspending substrate or other carrier media. The functionalizing coating is desirably immune to solvents used in the carrier media (e.g., liquid polymer, such as xylene, toluene, or methanol prior to it solidifying by release of aromatic gases or catalytic reaction).

Prior to discussing more specific implementations of NPs with PV cells or other solar energy system components, it should be understood that NPs exhibit two optical properties which act in opposition. These two properties are commonly known as “absorption” and “scattering.” The sum of these two properties is known as “extinction.” If the NPs are too densely distributed (e.g., within a carrier medium), then any beneficial action they may impart will be attenuated by absorption. On the other hand, if the NPs are insufficiently dense in their distribution, then the scattering aspect may be inadequate to perform any desired light manipulation. Although there have been attempts to mathematically model the optimal density of NPs for a given application, such have occurred with varying degrees of success. Additionally, attempts to empirically determine optimal density of the particles are often difficult to complete. For example, densities which are believed to be optimized when using a spectrophotometer for measurements are likely to be drastically lower in particle count when compared to optimization done in sunlight or with solar simulators at, for example, 1000-1500 photon watts per square meter (sometimes referred to as 1-1.5 “Suns”). Desirably, the particle density is to be optimized for the expected photon density in the application.

Thus, as can be seen from the above, there are a variety of variables to consider when implementing NPs in a solar energy system. For example, the following is a non-limiting list of variables that may be considered in the design of a component for a solar energy system which incorporates NPs: the size and shape of the NP; the type of material used to construct the NP; the functionalization or type of coating (or coatings) applied to the NP; the types of dyes to use with a NP, the refractive index of the carrier medium (e.g., solution or solid) into which the NPs are placed; the permittivity of the carrier medium in which the NPs are placed; the density and uniformity of the distribution of NPs within a carrier medium; the depth or thickness of the NP containing materials; the extinction profile (taking into account the absorption and scattering) of the particle over the spectrum of anticipated use; the resonant peak of the NP in its engineered environment. A Mie calculator, such as is available online from nanoComposix of San Diego, Calif., may be used in helping to determine the scattering and absorption characteristics of various NPs.

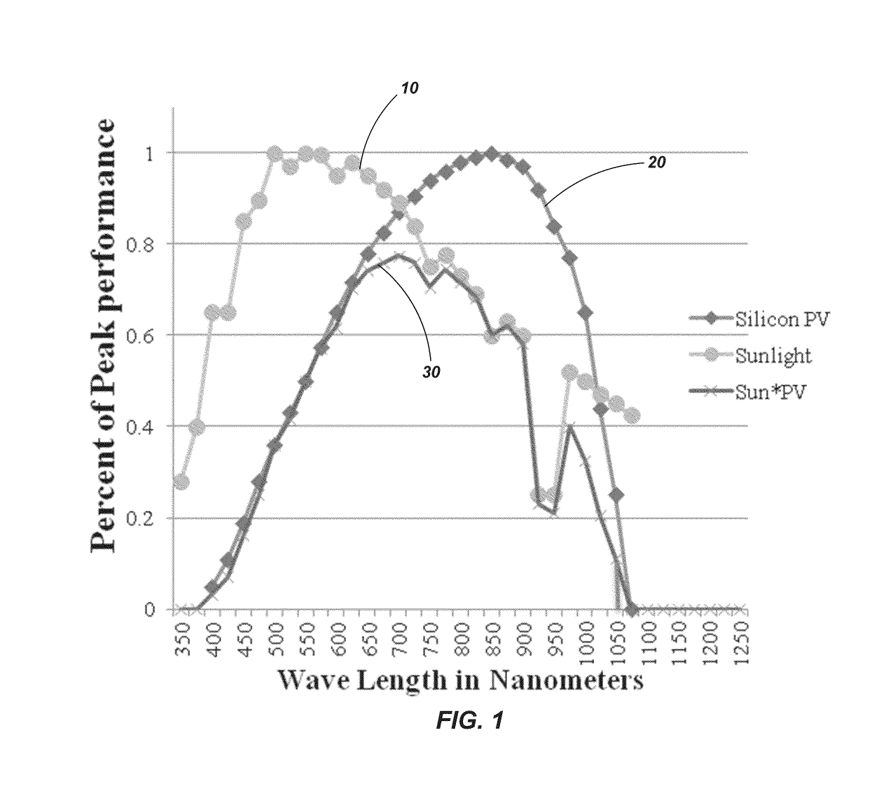

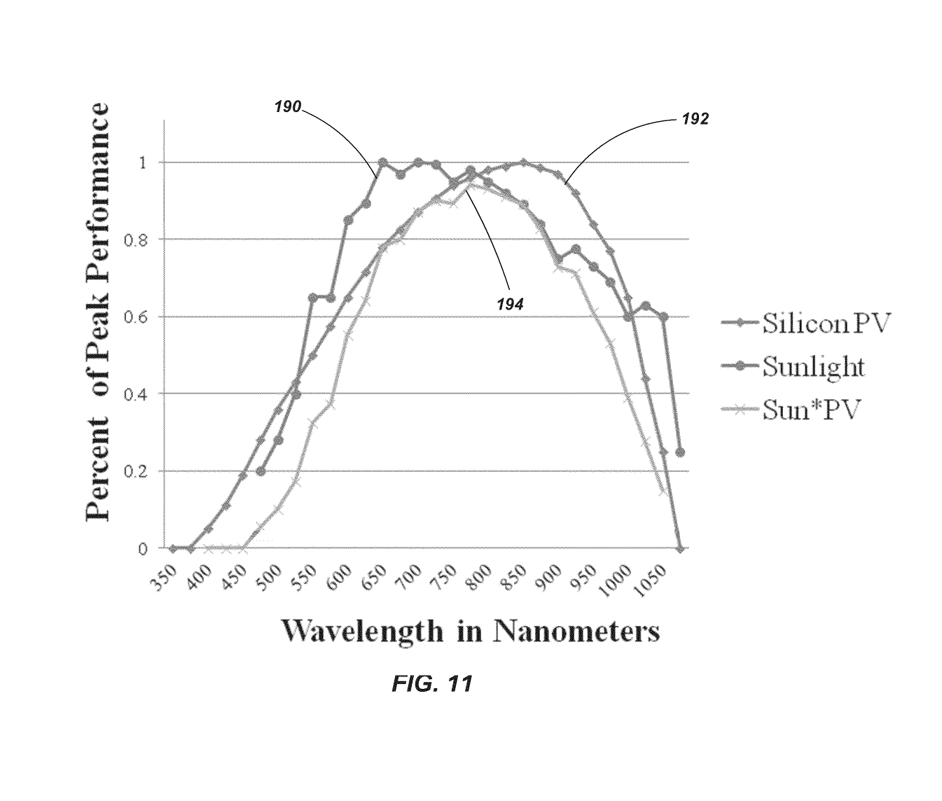

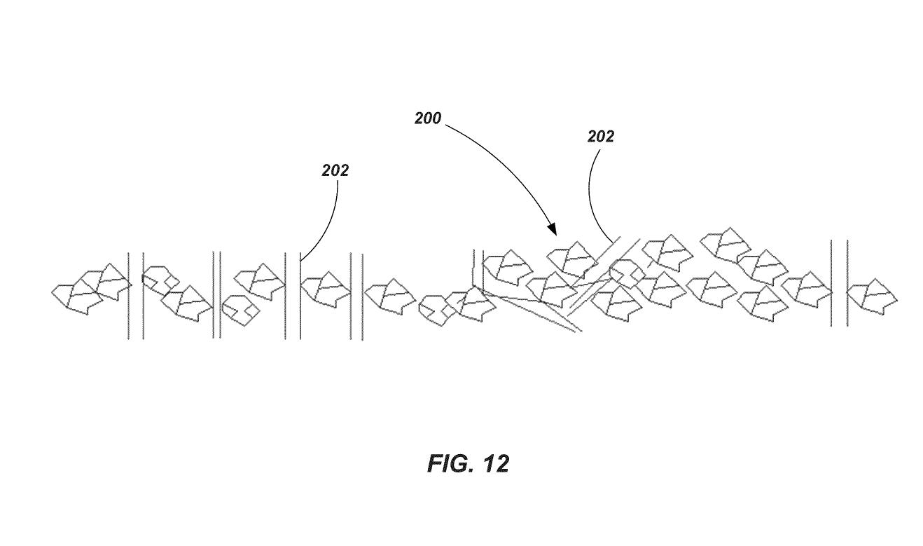

Referring to FIG. 11, a graph shows the effect of incorporating properly selected and distributed NPs within a solar energy system component (e.g., to manipulate the light prior to impinging on a PV cell). The NPs effect a wavelength shift to better match the wavelength of the available light with the sensitivity of the PV cell. In the example shown in FIG. 11, the sun's spectrum 190 is red shifted, for example, by approximately 125 nm, making it possible for the PV cell (having a sensitivity curve 192) to absorb and convert more energy from the available light. A third curve 194 shows the compatibility of the “red shifted” sun light with the sensitivity of the PV cell. A comparison of the graph in FIG. 11 with that of FIG. 1 shows that there is a greater common area beneath the first two curves 190 and 192 of FIG. 11 (as indicated by the third curve 194) when compared to the analogous curves shown in FIG. 1. While the graph shown in FIG. 11 specifically shows sun light that has been red shifted by a specific amount. Shifting of a greater or lesser amount is also contemplated by the present invention, as is “blue shifting.” For example, the sun produces high amounts of long wave infra-red light that is useless to a conventional silicon PV cell. This infra-red light may be blue shifted to make more energy available to the PV.

While not being bound by current theory, various phenomena understood in contemporary physics may be used to describe the mechanism whereby embodiments of the present invention are believed to work including inducing a red- or blue-shift of electromagnetic radiation.

In effecting a red or blue shift to available light, the present invention may take advantage of a plasmon effect produced by a layer of NPs. A plasmon may be described as a quantum of plasma oscillation. It is a quasiparticle derived from a quantization of plasma oscillations similar to the fact that photons are quantizations of electromagnetic oscillations (although the photon is an elementary particle, not a quasiparticle). Thus, plasmons are the collective oscillations of the free “electron gas density.” Photons may couple with plasmons and be manipulated. When plasmons are oscillating at optical frequencies with photons, another quasiparticle may be created called a “plasma polariton.”

Surface plasmon resonance mainly depends on the density of free electrons in the material. While not being limited to the example materials set forth below, the resonant wavelengths of plasmons most easily achieved by various metals relative to spectral areas are as follows: aluminum (Al)—ultra-violet; silver (Ag)—ultra-violet; gold (Au)—visible; copper (Cu)—visible. Plasmons are often described as an oscillation of free electron density with respect to the fixed positive ions in a metal. They oscillate at the plasma frequency until the energy is dissipated. Plasmons are a quantization of this kind of oscillation.

When interacting with plasmons, light having a wavelength smaller than that of the plasma frequency is reflected because the electrons in the metal screen the electric field of the light. On the other hand, light having a wavelength above the plasma resonant frequency is transmitted through the plasmon because the electrons cannot respond fast enough to screen it. In most metals, the plasma resonant frequency is in the ultraviolet, giving them the typical metallic sheen in visible light. Metals, such as copper and gold have interband transitions causing specific light wavelengths to be absorbed, and others to be reflected causing the appearance of their yellow-orange color. The plasmon energy can be estimated by the free electron model as follows:

$${E}_{p} = ℏ \sqrt{\frac{n {e}^{2}}{m {ε}_{o}}} = ℏ {ω}_{p}$$

where n is the conduction electron density, e is the elementary charge, m is the electron mass, ∈ₒ the permittivity of free space, the reduced Planck constant and ωₚ the plasmon resonant frequency.

Surface plasmons are confined to surfaces and that interact with light to form a polariton. They can occur at the boundary of a vacuum and a material having a small positive “imaginary” and large negative “real” dielectric constant such as in metal or a doped dielectric. Production of surface plasmons in the optical range is much more difficult and it has only recently become possible to reliably reproduce them.

In addition to effecting a wavelength shift, metal nanoparticles may be deposited on a substrate at a distance from a PV cell in order to trap the light between the NPs and the PV cell. Metallic NPs (including composite NPs) can be used to couple and trap freely propagating plane waves into a PV cell.

The optical properties of metallic and composite NPs have been described in the literature and mathematically modeled to optimize photon capture. Surface Effects Raman Scatter (SERS) as a light capture method has experimentally been proven as a PV cell enhancement. Proper design and geometric distribution of NPs in a PV cell or related component enables improved conversion of the photon energy into an electromotive force. Moreover particular geometrical arrangements of metallic and composite NPs have been demonstrated to cause a spectral shift of up to 200 nm. When the solar spectrum is red shifted 200 nm, the peak energy more nearly corresponds to the spectrum of photon reception of silicon PVs. However, there have remained significant barriers to the broad application of this nanoparticle technology to use in solar energy applications. One such barrier has included obtaining and maintaining the proper geometry and spacing of the NPs and how to incorporate them into a solar module—including retrofitting or upgrading existing modules.

In prior art, the distribution and attaching of NPs to the surface of a PV cell has often been by vacuum deposit of NPs using sputter coating. Sputter coating is a long and well established method of applying a metallic layer including forming trace lines for integrated circuits (IC). Sputter coating is designed to lay down a completely conductive path between two points on a semiconductor substrate. A very thin Ag sputter coating can be applied to a surface of a PV cell which is designed to admit light from the sun and to also internally reflect light that is not initially absorbed by the PV cell until it is more fully absorbed by the PV cell. However, the distribution of particles in a sputter coated layer is a function of probability as described by the Poisson distribution. Particles which are distributed according to probability are rarely at an optimal density or geometrical spacing. Rather, they will variously be either too compacted to allow light passage or too scattered to effectuate proper light trapping or other light manipulation. FIG. 12 illustrates a sputter coated layer 200 showing the variability of the deposited irregular shapes produced by such a process. Since sputter coating is a random process, a random distribution results. FIG. 12 also illustrates the interaction of incident light 202 with a generally translucent layer 200 of sputter coated Ag NPs. Random blockages of light 202 and random sub optimal distribution of light pathways is inherent with this prior art method of coating silver NPs.

As illustrated in FIG. 12, the sputter coating method of creating a thin film for SERS or spectrum shifting relies on the probability of nanoparticle deposit following the Poisson distribution at any distinct point. This would suggest that the probability of a useful area, wherein the NPs are in the correct geometry with correct spacing, is very low. It is much more probable that stacks of particles more generally occur which completely block the passage of photons rather than the occasional small useful areas which might exhibit the spacing and positioning of particles that create the desired optical effects.

In one embodiment of the present invention, silver NPs which are predominately spherical may be suspended in a clear liquid gelatin (in the sol state) or liquid polymer. Such NPs with a high Zeta charge are available, for example, from Attostat, Inc. of Salt Lake City, Utah, or from Truetech Laser Corporation of North Salt Lake City, Utah. Larger gold and silver NPs (e.g., 150 nm or greater in diameter), with and without silica coating, are available from nanoComposix of San Diego Calif. In certain embodiment, it is desirable for the NPs used in this manner to have a high zeta charge. Spherical NPs may be produced having an absolute zeta charge (i.e., positive or negative) of approximately 30 mV or greater. In one embodiment, the NPs may be produced to exhibit an absolute zeta charge of approximately 45-60 mV. In another embodiment, the NPs may exhibit an absolute zeta charge of greater than approximately 60 mV.

The NPs with a high zeta charge with the same polarity tend to be repulsed by one another. Thus when NPs with a high zeta charge are suspended in a low viscosity fluid, the NPs tend to distribute themselves in a statistically uniform array. The operational strength of the plasmons formed from the NPs will be optimized when the proper density and proper distribution of NPs is achieved. In one embodiment, such inter-sphere spacing may be approximately equal to the diameter of the NPs being used. This tends to be a very good range for the Surface Effects Rahman Scatter (SERS) phenomenon of light trapping to function. Considering the example of spherical NPs distributed, at least in part, due to zeta charges, and where spacing is desired to be approximately equal to the diameter of the NPs, statistically uniform spacing may be achieved to a level where the standard deviation in spacing equals, for example, approximately the diameter of the NPs multiplied by 0.2.

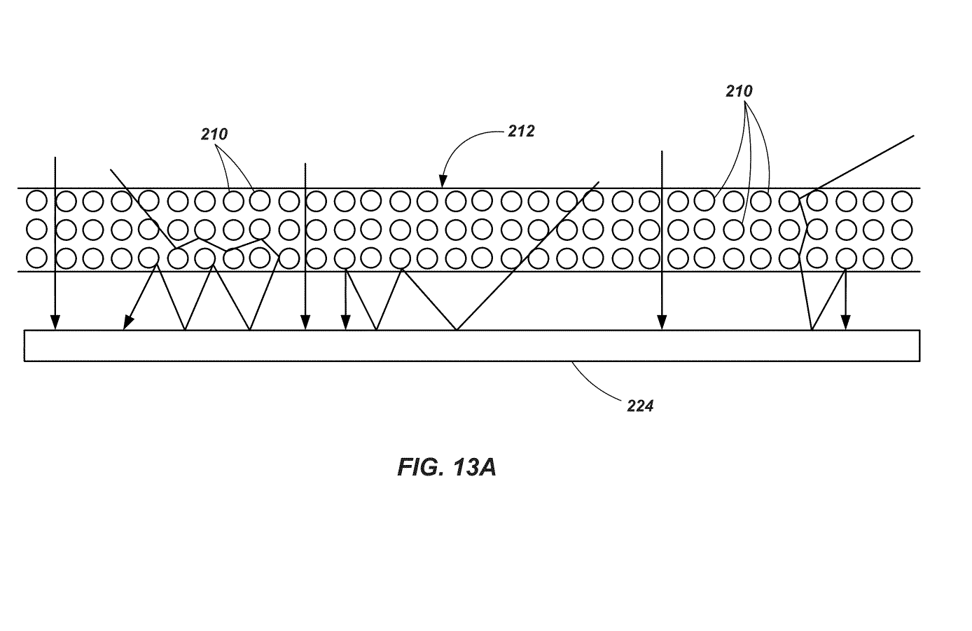

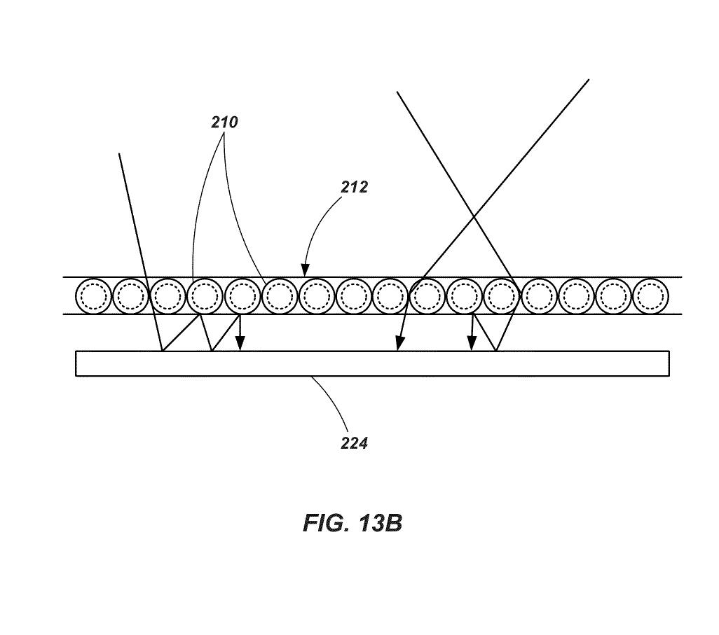

As seen in FIG. 13A, a plurality of spherical NPs 210 having a high Zeta charge may be evenly distributed in a carrier medium 212 to manipulate light entering between the openings. Once below the layer of NPs, the light remains trapped, reflected and re-reflected until absorbed by the PV cell 224 when the light becomes oriented nearly perpendicular to the surface of the PV cell 224.

In another embodiment, as shown in FIG. 13B, instead of relying on high zeta charge nanoparticles for precision nanoparticle placement, the NPs 210 comprise composite NPs. Considering the example of a composite NP having a core formed of a metallic material and a shell formed of another material such as silica, it is noted that the optical properties of the silica shells will help to create uniform spacing of a desired distance between the metallic NPs 210 for the attainment of a structure most suited to trapping light. In embodiments where the NPs are packed within a carrier medium such that they are contiguous with one another, the transparent coatings provide spacing between adjacent metallic cores. In such an embodiment, the uniformity of the spacing will be determined largely by manufacturing tolerances of the NPs, including the coatings. In various embodiments (whether relying on shells or zeta charge for spacing), the spacing between the NPs may range from 10% to 150% of the average diameter of the NPs (or the diameter of the metallic cores, depending on the embodiment).

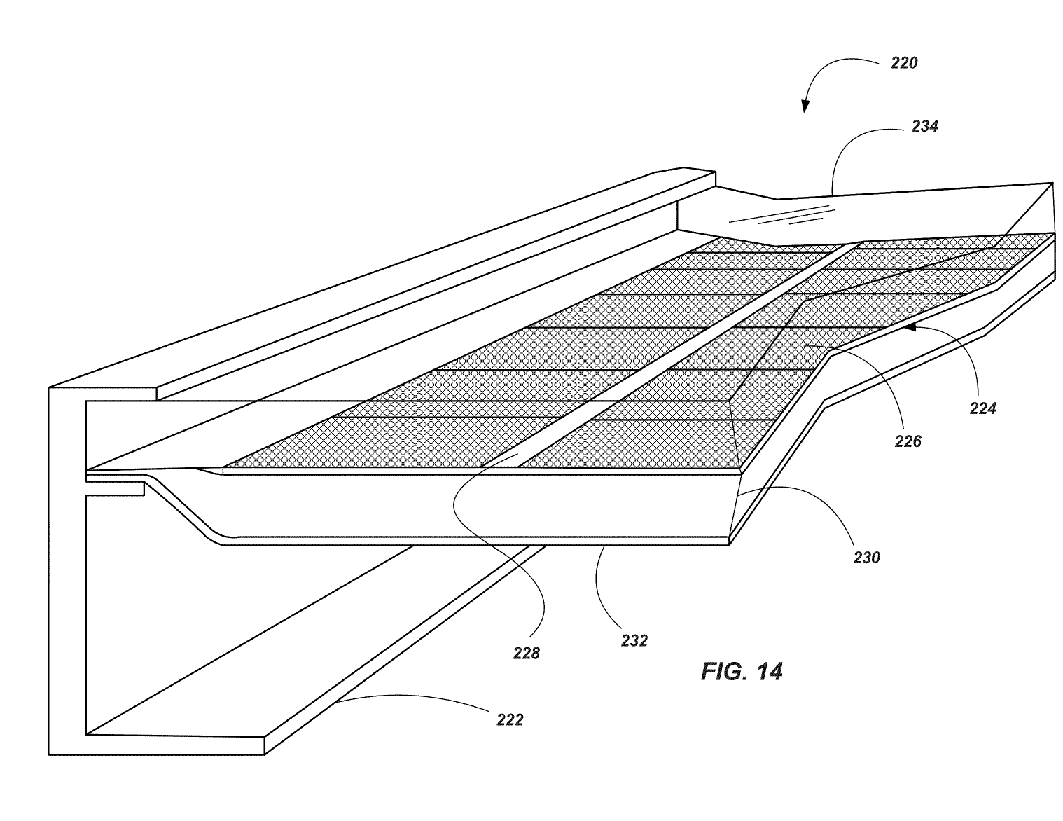

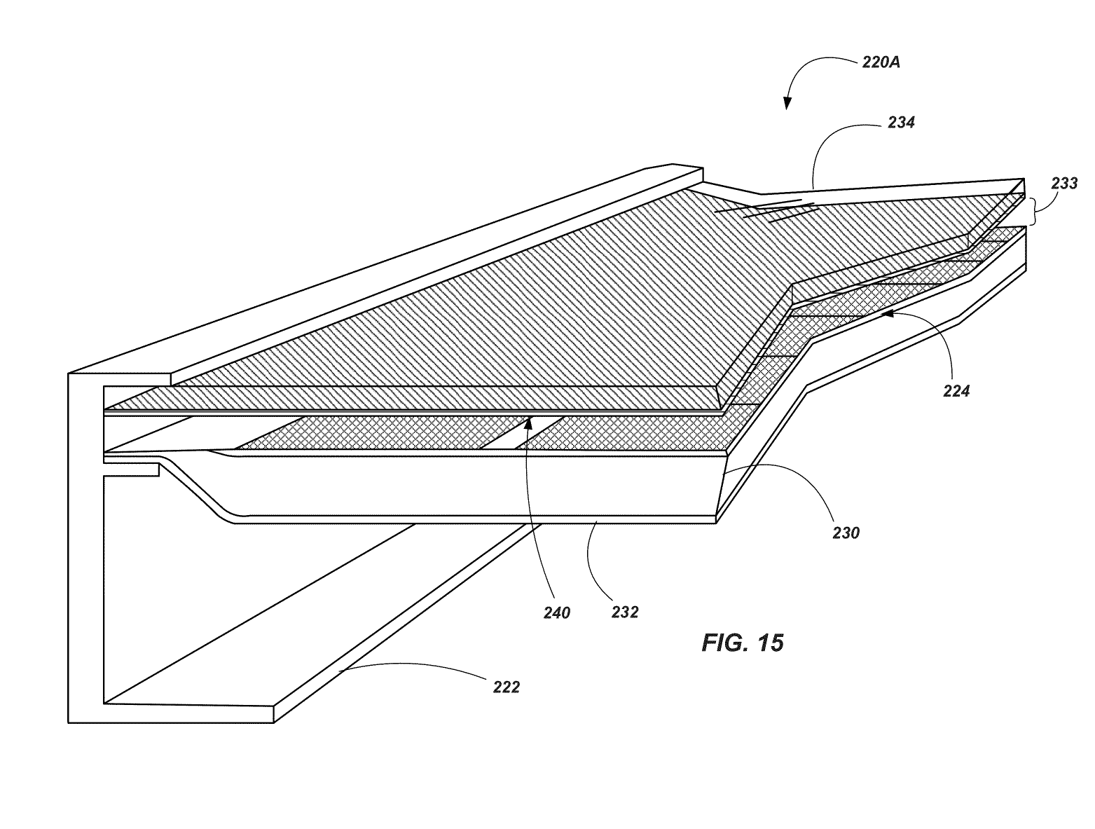

Referring now to FIG. 14, a partial cross section of a conventional solar module 220 is shown. The module 220 includes a frame 222 that houses a PV cell 224. The PV cell 224 (which may actually include an array of cells) includes a crystalline photovoltaic 226 that is communication with a bus line 228. The bus line 228 carries electrical energy generated by the crystalline photovoltaic 226 to equipment for conditioning and distribution of the electrical energy. The PV cell 224 may include a variety of features, as will be appreciated by those of ordinary skill in the art, such as an antireflective coating to retain as much of the incident light that strikes the PV cell 224 as possible. A protective layer 230, which may include a polymer material, may be provided to protect the PV cell 224 from shock as well to provide protection from moisture or other environmental influences. A backing material 232 may be bonded to the back of the protective layer 230 to assist in sealing the assembly. A layer of glazing 234 is placed above the PV cell 224 and is coupled with the frame 222. The glazing 234 additionally provides environmental protection to the PV cell 224.

In operation, photons pass through the glazing 234 and are absorbed by the semiconducting materials of the crystalline photovoltaic 226. Negatively charged electrons are then freed from their atoms creating an electric potential. The electric potential produces an electric current along the bus line 228 as a direct current (DC) of electricity.

The present invention includes the addition of a thin layer of material including a plurality of NPs. For example, the NPs may be disposed in a thin substrate or film layer or they may be dispersed in a coating of material applied to an existing substrate. In another embodiment, the NPs may be embedded in a component of the solar module such as a layer of glazing material. The layer may be as thin as a fraction of a millimeter, which is easily adapted to use in commercial solar modules such as that shown in FIG. 14.

One embodiment of a solar module 220A that incorporates one more NP material layers 240 is shown in FIG. 15. The solar module 220A is similar to that which is described in FIG. 14 and includes a frame 222 that houses a PV cell 224. The PV cell 224 includes a crystalline photovoltaic 226 that is communication with a bus line 228. A protective layer 230 and a backing material 232 may provide environmental protection to the PV cell 224. A layer of glazing 234 is placed above the PV cell 224 and coupled with the frame 222. A material layer 240 having a plurality of NPs is positioned between the layer of protective glazing 234 and the PV cell 224. For example, the NP material layer 240 may be adhered to or coated on the undersurface of the glazing 234. In some embodiments, there may be an air gap 233 or other transparent material positioned between the NP material layer 240 and the PV cell 224. In some embodiments, an NP material layer may be sandwiched between the glazing 234 and the PV cell 224.

The NP material layer 240 is designed and constructed to receive sunlight and effect a wavelength shift (e.g., a red shift) of the sunlight prior to the sunlight reaching the PV cell 224, as well as to provide light trapping of the sunlight not immediately absorbed by the PV cell 224. The NP material layer 240 may include a plurality of a single type of NPs (e.g., the composite NP 110 shown in FIG. 3), or it may include a plurality NPs of different types and/or sizes depending on the desired wavelength shift and light trapping effects to be provided by the NP material layer 240.

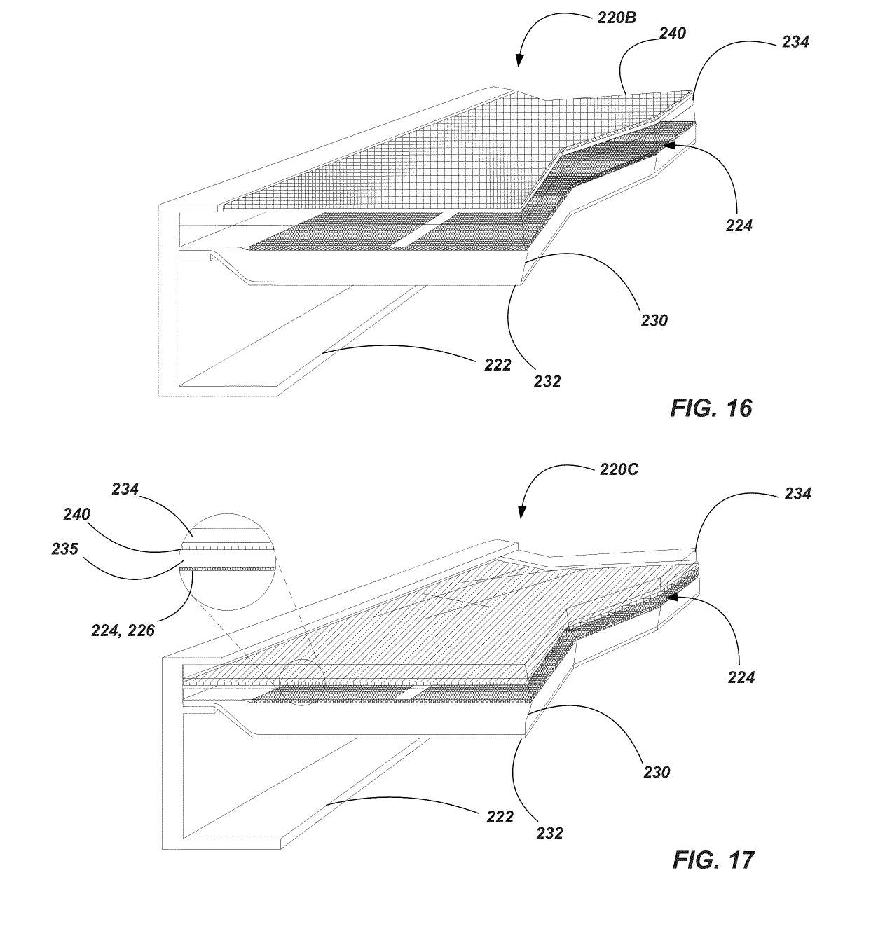

Referring to FIG. 16, another embodiment of a solar module 220B is shown. The solar module includes a frame 222 that houses a PV cell 224. The PV cell 224 includes a crystalline photovoltaic 226 that is communication with a bus line 228. A protective layer 230 and a backing material 232 may provide environmental protection to the PV cell 224. A layer of glazing 234 is placed above the PV cell 224 and coupled with the frame 222. An NP material layer 240 is positioned atop of the protective glazing 234 such that the glazing 234 is between the NP material layer 240 and the PV cell 224. The NP material layer 240 may be formed as a film and adhered to the glazing 234 with an appropriate adhesive material or it may be spray coated directly onto the glazing 234. Non-limiting examples of optically clear adhesives that may be used include 8171CL and 8172CL available from 3M Corporation.

FIG. 17 shows yet another embodiment of a solar module 220C having a frame 222 that houses a PV cell 224. As with previously described solar modules, the PV cell 224 includes a crystalline photovoltaic 226 that is communication with a bus line 228. A protective layer 230 and a backing material 232 may provide environmental protection to the PV cell 224. A layer of glazing 234 is placed above the PV cell 224 and coupled with the frame 222. An NP material layer 240 may be sandwiched between two layers of glass, such as the layer of protective glazing 234 and another layer of glass 235 positioned directly above the PV cell 224.

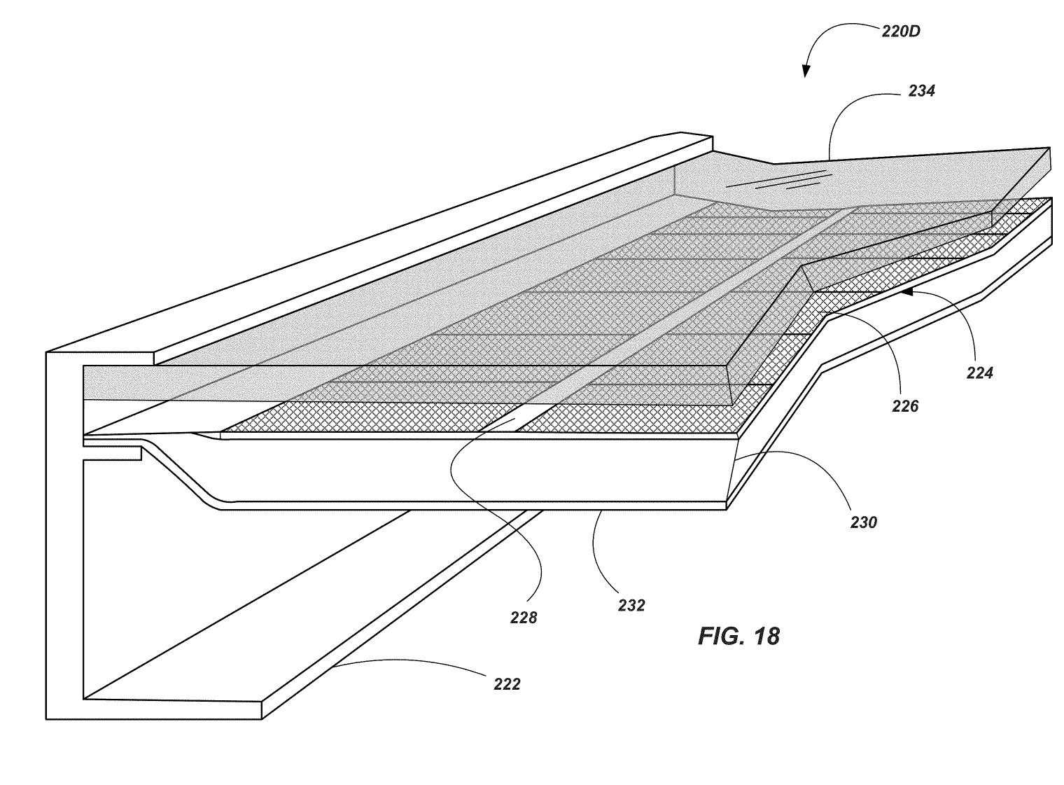

FIG. 18 shows a further embodiment of a solar module 220D having a frame 222 that houses a PV cell 224. As with previously described solar modules, the PV cell 224 includes a crystalline photovoltaic 226 that is communication with a bus line 228. A protective layer 230 and a backing material 232 may provide environmental protection to the PV cell 224. A layer of glazing 234 is placed above the PV cell 224 and coupled with the frame 222. A plurality of NPs are embedded within the layer of glazing 234. In one embodiment, the layer of glazing 234 may abut the PV cell 224. In another embodiment, a transparent material gap (e.g., an air gap) may exist between the NP embedded glazing 234 and the PV cell 224.

It will be recognized that the example embodiments described above may be produced as original (OEM) equipment, or may be implemented as a “retrofit” to existing solar modules. For example, an NP layer may be applied to existing solar modules by applying a thin film NP material layer to an existing solar module. In another embodiment, the NP material layer may be formed by spray coating a portion of an existing solar module. In a further embodiment, certain components may be removed and replaced (e.g., the glazing layer) with a new component that includes an NP material layer.

In one particular example, a plurality of composite NPs may be distributed in a polymer material. The NPs may include a substantially spherical, silver core that is approximately 200 nm in diameter. The NPs may further include a silica shell or coating around the silver core exhibiting a thickness of approximately 15 nm that is functionalized or otherwise tailored for disposal in the polymer material.

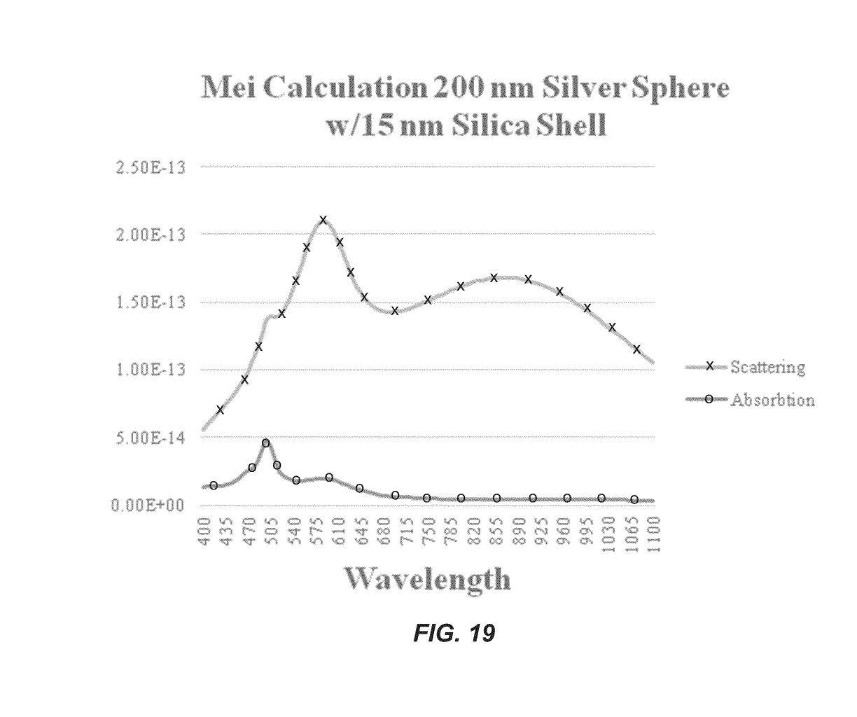

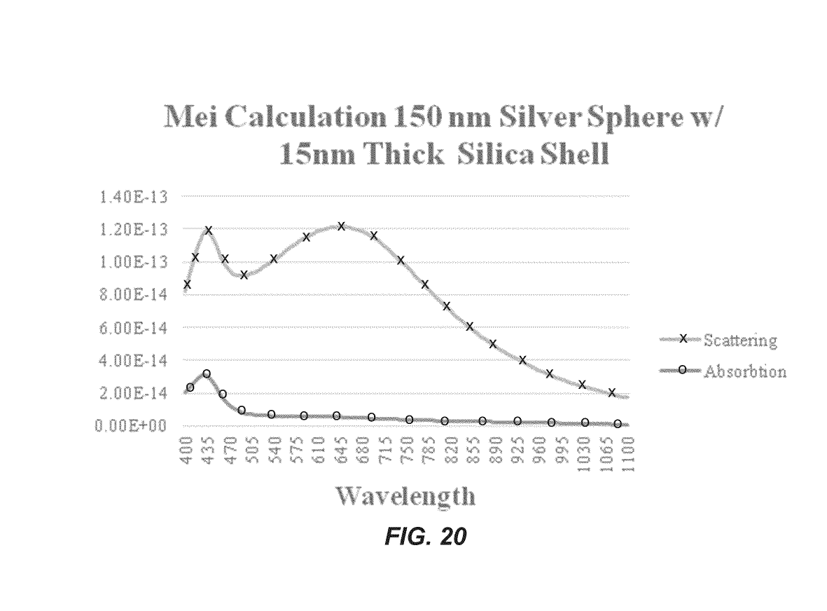

FIG. 19 includes a graph depicting the results of a Mei's calculation for such an NP. The graph shows wavelength (in units of nm) along the horizontal axis, while the vertical axis is depicted in units of area (nm²). The graph depicts the Mie solution to Maxwell's equations showing the scattering of electromagnetic radiation by a sphere. As seen in FIG. 19, the scattering function of the described NPs is high across most of the selected spectrum as compared with absorption across the same spectrum. For purposes of comparison, FIG. 20 illustrates a similar graph for NPs that include a spherical silver core that are 150 nm in diameter and have a silica coating that is 15 nm thick. The scattering for the NPs depicted in FIG. 20 is substantially lower than those depicted in FIG. 19.

The polymer material into which the NPs will be dispersed includes a “clear coat” material known to automobile manufacturers under the trade name of Medallion RS-6100 European Clear. The polymer is a two part system with a clear coat (part A) and an activator (part B) mixed in a ratio of 2:1.

In preparing the polymer, part A is dispensed into a clean mixing vessel and the number of NPs necessary to obtain a desired density is calculated. The NPs are suspended in a liquid compatible with the polymer such as toluene. The NP solution is then agitated until the NPs and liquid fully in solution. This may be done by shaking or other agitation or it may require approximately 30 seconds of sonication with an ultrasonic water bath. However, it is noted that over-sonication may result in unwanted aggregation.

The liquid containing the NPs is measured using a clean pipette or other precision aspiration device and then dispensed into the vessel containing part A of the liquid polymer. The two liquids may then be gently mixed together for about 30 minutes using a magnetic stirrer or other mixer, being careful not to entrain air into the mixture. The mixing may be followed by placing the mixture in a vacuum to remove any entrained air.

Part B of the polymer may be added in the appropriate ratio to the mixing vessel containing the NP solution and part A. Up to 5% of compatible reducer may be added as required for subsequent application of the resulting solution. The solution may then be mixed for approximately 5 minutes. Usable pot life should be approximately 2-3 hours.

The liquid polymer mixture may be coated atop most clear solid substrates. The solution may be applied to a substrate using a variety of methods. In One method of application includes spraying the solution at 40-45 psi using a conventional spray gun, and 8-10 psi using a high-volume, low-pressure (HVLP) spray gun. If multiple coats are desired then, the method may include a flash cure for approximately 5 minutes between coats. In another method, spin coating may be used to apply the solution to a substrate. In a further example, a wire wound rod may be used to evenly disperse the NP/polymer solution on a substrate at a desired thickness. In yet a further example, the solution may be cast to a desired size and geometry.

In other examples of using NPs with a solar module, nano-rods and/or nano cones may be grown atop the surface of a substrate (e.g., the cover glass or glazing layer). The grown NPs may act as light gathering and redirecting devices for light which impinges the solar panel at angles which are not optimal for photon absorption by the silicon PV cell. Various methods of growing these nanoparticles may be employed and may be accomplished strictly through chemistry or may be done by controlling the temperature and pressure of the atmosphere during NP growth.

There are a variety of benefits of incorporating NPs with solar modules, including applying NPs to substrates other than the PV cell itself. Each of the above examples provides an economic or process advantage over directly applying the nanoparticles to the PV cell. Other advantages provided by embodiments of the present invention include enhanced light trapping ability of a nanoparticle plasmon which is best served with a small optically transparent material gap between the plasmon and the surface of the PV cell. As noted above, this optically transparent material gap may include a layer of optically transparent material (e.g., a substrate) between the plasmon and the PV surface, it may include a gap substantially filled with air disposed between the plasmon and the PV cell, or it may include both.

The ability of applying NPs to a polymer web, or plastic film, which then can be placed on a component of a solar module provides significant manufacturing convenience, especially when direct application of NPs to a PV cell would interfere with its electrical generating capacity or be incompatible with other manufacturing processes.

Another advantage provided by the present invention is the ability to easily and efficiently apply multiple layers of NPs to a solar module in a variety of configurations. Multiple NP layers may be simultaneously used to create desired effect such as wavelength shifting or light trapping. For example it may be desirable to include one or more NP layers devoted to wavelength shifting and one or more additional NP layers devoted to light trapping. Certain configurations of NP layers may be incompatible when used directly together and may need to be configured as layers separated by a substrate.

It is note that any feature or element of one described embodiment may be combined with any other embodiment without limitation. Any and all combinations of the above embodiments may be used in concert to enhance the performance of a PV cell in gathering sunlight.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention includes all modifications, equivalents, and alternatives falling within the spirit and scope of the invention as defined by the following appended claims.

What is claimed is:

1. A solar energy apparatus, comprising:
a photovoltaic (PV) cell;
a material layer associated with the PV cell having a plurality of nanoparticles (NPs) which are each spaced from adjacent NPS at intervals approximately 10% to 150% of an average NP diameter, wherein the material layer is positioned relative to the PV cell to provide an optically transparent material gap between the NPs and the PV cell.

2. The solar energy apparatus of claim 1, wherein the NPs comprise at least one of silver, gold, and copper.

3. The solar energy apparatus of claim 2, wherein the NPs include a metallic core and a substantially transparent shell.

4. The solar energy apparatus of claim 3, wherein the shell is comprised of silica.

5. The solar energy apparatus of claim 4, wherein the shell exhibits a thickness of approximately 10 to 20 nanometers.

6. The solar energy apparatus of claim 1, wherein the NPs exhibit an absolute value zeta charge of approximately 30 mV or greater.

7. The solar energy apparatus of claim 6, wherein the NPs exhibit an average diameter of approximately 2 nanometers to approximately 10 nanometers.

8. The solar energy apparatus of claim 1, wherein the NPs are substantially spherical and exhibit an average diameter of approximately 10 to approximately 250 nanometers.

9. The solar energy apparatus of claim 1, wherein the NPs include triangular platelets exhibiting a height from a base to an apex of approximately 150 nm and a thickness of approximately 10 to approximately 40 nm.

10. The solar energy apparatus of claim 1, wherein the NPs exhibit an inter-sphere spacing of approximately fifty percent to approximately 300 percent of the diameter of the NPs

11. A method of manufacturing a solar energy apparatus, the method comprising:
providing a photovoltaic (PV) cell;
disposing a plurality of nanoparticles (NPs) adjacent to the PV cell to create a plasmon having an optically transparent material gap between the plasmon and the PV.

12. The method of claim 11, wherein disposing a plurality of NPs adjacent to the PV includes disposing a plurality of composite NPs.

13. The method of claim 12, further comprising providing NPs with a metallic core and an optically transparent shell.

14. The method of claim 13, further comprising suspending the NPs in a solution, the NPs exhibiting a substantially uniform spacing, wherein the substantially uniform spacing is controlled, at least in part, by the thickness of the NPs shells.

15. A method of retrofitting a solar energy device having a photovoltaic (PV) cell, the method comprising:
disposing a plurality of nanoparticles (NPs) adjacent to the PV cell to create a plasmon having an optically transparent material gap between the plasmon and the PV cell.

16. The method of claim 15, further comprising disposing the plurality of NPs on an existing substrate of the solar energy device positioned above the PV cell.

17. The method of claim 16, further comprising placing a film containing the plurality of NPs on the substrate.

18. The method of claim 15, further comprising replacing an existing substrate of the solar energy cell with a new substrate including the plurality of NPs.

19. A method of manufacturing a substrate, comprising:
providing an aqueous solution containing high zeta charge, substantially spherical nanoparticles (NPs);
forming a gelatin of the solution;
coating a transparent polymer web substrate with the gelatin;
removing moisture from the coated polymer web.

20. The method of claim 19, further comprising providing the NPs as silver NPs.

21. The method of claim 20, wherein the NPs exhibit an absolute value zeta charge of approximately 30 mV or greater.

22. The method of claim 19, further comprising providing the NPs at a size exhibiting an average diameter of approximately 50 nanometers to approximately 250 nanometers.

23. The method of claim 19, further comprising suspending the NPs within the solution at a substantially uniform distribution exhibiting an inter-nanoparticle spacing of approximately 50 percent to 250 percent of the diameter of the NPs.

24. The method of claim 19, wherein forming a gelatin of the solution includes forming a gelatin comprising polyurethane.
